(19) United States
(12) Patent Application Publication
(10) Pub. No.: US 2023/0320176 A1
(43) Pub. Date: Oct. 5, 2023

(54) LIGHT EMITTING DISPLAY APPARATUS

(71) Applicant: LG Display Co., Ltd., Seoul (KR)

(72) Inventor: JoonYoung HEO, Gyeonggi-do (KR)

(73) Assignee: LG Display Co., Ltd., Seoul (KR)

(21) Appl. No.: 18/125,017

(22) Filed: Mar. 22, 2023

(30) Foreign Application Priority Data
Mar. 29, 2022 (KR) 10-2022-0039022
May 13, 2022 (KR) 10-2022-0058978

(51) Int. Cl. H10K 59/80; G09G 3/3233; H10K 59/12; H10K 59/122

(52) U.S. Cl. CPC H10K 59/873; G09G 3/3233; H10K 59/1201; H10K 59/122; G09G 2300/0842; G09G 2320/0214; G09G 2320/0233

(57) ABSTRACT

A light emitting display apparatus can include a substrate including a display area and a non-display area surrounding the display area, a circuit layer on the substrate, a planarization layer on the circuit layer, and a dam disposed on the planarization layer and located at a boundary between the display area and the non-display area. Also, the light emitting display apparatus can further include a division portion disposed on the dam, the division portion extending along the dam; a display area emission layer disposed in the display area; a non-display area emission layer disposed outside the dam, the dam being located between the display area emission layer and the non-display area emission layer; and a division portion emission layer disposed on an upper surface of the division portion. The division portion emission layer can be separated from the display area emission layer and the non-display area emission layer.

### CROSS-REFERENCE TO RELATED APPLICATIONS

This application claims the benefit of and priority to Korean Patent Application No. 10-2022-0039022 filed in the Republic of Korea on Mar. 29, 2022, and Korean Patent Application No. 10-2022-0058978 filed in the Republic of Korea on May 13, 2022, the entireties of all these applications are hereby expressly incorporated by reference as if fully set forth herein.

### BACKGROUND

### Field of the Invention

The present disclosure relates to a light emitting display apparatus.

### Discussion of the Related Art

A light emitting display apparatus having almost no non-display area is referred to as a seamless light emitting display apparatus.

Since the non-display area is very small in the seamless light emitting display apparatus, it is often difficult to remove the emission layer provided in the non-display area. In this situation, since moisture can permeate through the emission layer provided in the non-display area, the emission layer is separated using a structure provided outside a dam.

However, since a separate structure must be added outside the dam, there is a limitation in reducing a size of the non-display area and a larger than desired bezel area may result.

### SUMMARY OF THE DISCLOSURE

Accordingly, the present disclosure is directed to providing a light emitting display apparatus that substantially obviates one or more problems due to limitations and disadvantages of the related art.

An aspect of the present disclosure is directed to providing a light emitting display apparatus in which an emission layer is separated using a division portion provided at an upper end of a dam.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these and other advantages and in accordance with the purpose of the disclosure, as embodied and broadly described herein, there is provided a light emitting display apparatus including a substrate including a display area displaying an image and a non-display area surrounding the display area, a circuit layer provided on the substrate, a planarization layer provided on the circuit layer, a dam provided on the planarization layer and provided at a boundary between the display area and the non-display area, a division portion provided on the dam along the dam, a display area emission layer provided in the display area surrounded by the dam, a non-display area emission layer provided outside the dam, and a division portion emission layer separated from the display area emission layer and the non-display area emission layer and provided at an upper surface of the division portion.

It is to be understood that both the foregoing general description and the following detailed description of the present disclosure are explanatory and are intended to provide further explanation and examples of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is an example diagram illustrating a configuration of a light emitting display apparatus according to an embodiment of the present disclosure;

FIG. 2 is an example diagram illustrating a structure of a pixel applied to a light emitting display apparatus according to an embodiment of the present disclosure;

FIG. 3 is a perspective view illustrating a front portion of a light emitting display apparatus according to an embodiment of the present disclosure;

FIG. 4 is a perspective view illustrating a rear portion of the light emitting display apparatus according to an embodiment of the present disclosure;

FIG. 5 is an example diagram illustrating a cross-sectional surface view taken along line A-A′ illustrated in FIG. 1 and FIG. 3 according to an embodiment of the present disclosure;

FIGS. 6A to 6F are example diagrams illustrating a method of manufacturing a light emitting display apparatus according to an embodiment of the present disclosure;

FIG. 7 is another example diagram of a display panel configuring a light emitting display apparatus according to an embodiment of the present disclosure;

FIG. 8 is an example diagram illustrating a cross-sectional surface view taken along line B-B′ illustrated in FIG. 7 according to an embodiment of the present disclosure; and

FIG. 9 is an example diagram illustrating a cross-sectional surface view taken along line C-C′ illustrated in FIG. 7 according to an embodiment of the present disclosure.

### DETAILED DESCRIPTION OF THE EMBODIMENTS

Reference will now be made in detail to the example embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. When “comprise,” “have,” and “include” described in the present specification are used, another part can be added unless “only” is used. The terms of a singular form can include plural forms unless referred to the contrary.

In construing an element, the element is construed as including an error or tolerance range although there is no explicit description of such an error or tolerance range.

In describing a position relationship, for example, when a position relation between two parts is described as, for example, “on,” “over,” “under,” “below,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a situation that is not continuous can be included unless a more limiting term, such as “just,” “immediate(ly),” or “direct(ly)” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first,” “second,” “A,” “B,” “(a),” “(b),” etc. can be used. These terms are intended to identify the corresponding elements from the other elements, and basis, order, or number of the corresponding elements should not be limited by these terms. The expression that an element is “connected,” “coupled,” or “adhered” to another element or layer the element or layer can not only be directly connected or adhered to another element or layer, but also be indirectly connected or adhered to another element or layer with one or more intervening elements or layers “disposed,” or “interposed” between the elements or layers, unless otherwise specified.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in co-dependent relationship.

Hereinafter, embodiments of the present disclosure will be described in detail with reference to the accompanying drawings.

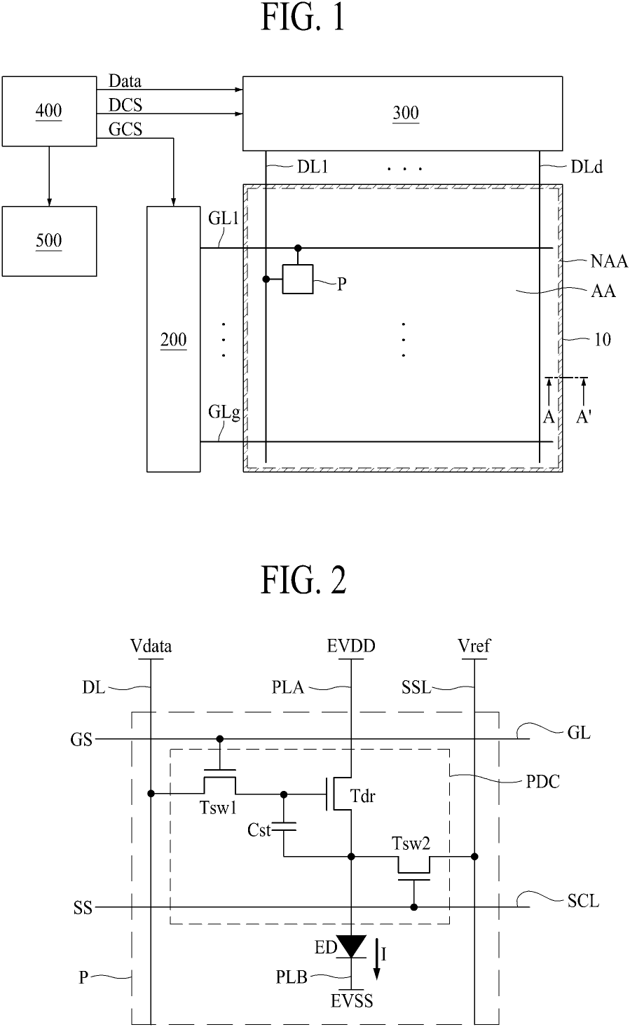

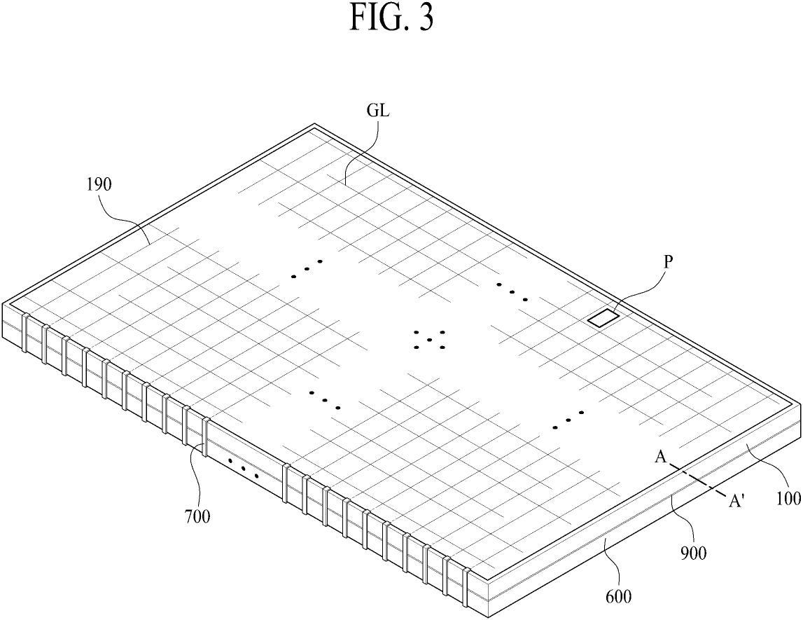

FIG. 1 is an example diagram illustrating a configuration of a light emitting display apparatus according to an embodiment of the present disclosure and FIG. 2 is an example diagram illustrating a structure of a pixel applied to a light emitting display apparatus according to an embodiment of the present disclosure.

The light emitting display apparatus according to an embodiment of the present disclosure can configure various electronic devices. The electronic devices can include, for example, smartphones, tablet personal computers (PCs), televisions (TVs), and monitors.

The light emitting display apparatus according to an embodiment of the present disclosure, as illustrated in FIG. 1, can include a display panel 10 which includes a display area (or active area) AA displaying an image and a non-display area (or non-active area) NAA provided outside the display area AA, a gate driver 200 which supplies a gate signal to a plurality of gate lines GL1 to GLg provided in the display panel 10, a data driver 300 which supplies data voltages to a plurality of data lines DL1 to DLd provided in the display panel 10, a controller 400 which controls driving of the gate driver 200 and the data driver 300, and a power supply 500 which supplies power to the controller 400, the gate driver 200, the data driver 300, and the display panel 100. Here, g and d can be positive integers.

Particularly, in the light emitting display apparatus according to an embodiment of the present disclosure, stages included in the gate driver 200 can be provided in the display area AA, and the gate lines GL1 to GLg connected to the stages can be provided in the display area AA. Hereinafter, for convenience of description, the display area AA and the non-display area NAA can be divided by using the dam as a boundary.

First, the display panel 10 can include the display area AA and the non-display area NAA.

Pixels P for displaying image are provided in the display area AA and the non-display area NAA can surround the display area AA.

As described above, because the gate driver 200 connected with gate lines GL1 to GLg can be provided in the display area AA, a non-display area for the gate driver 200 can be omitted. Accordingly, a width of the non-display area NAA can be reduced compared to the related art.

The gate lines GL1 to GLg, the data lines DL1 to DLd, and the pixels P can be provided in the display area AA. Also, stages configuring the gate driver 200 can be provided in the display area AA. Accordingly, the display area AA can display an image. Here, g and d can each be a natural number.

However, in the present disclosure, the gate driver 200 is not necessarily provided in the display area AA. That is, since the present disclosure is intended to reduce the width of the non-display area NAA, the present disclosure can be applied to all types of light emitting display apparatuses.

The pixel P included in the display panel 10, as illustrated in FIG. 2, can include a pixel driving circuit PDC, including a switching transistor Tsw1, a storage capacitor Cst, a driving transistor Tdr, and a sensing transistor Tsw2, and a light emitting device ED.

A structure of the pixel P provided in the display panel 10 is not limited to a structure illustrated in FIG. 2. Accordingly, a structure of the pixel P can be changed to various shapes.

An insulation layer and various electrodes configuring the pixels P can be provided on a first base substrate, such as a glass substrate, a flexible substrate or a film. That is, the display panel 10 can include a first base substrate, a plurality of insulation layers provided on the first base substrate, and a plurality of electrodes provided on the first base substrate.

The data driver 300 can supply data voltages Vdata to the data lines DL1 to DLd.

The controller 400 can realign input image data transferred from an external system by using a timing synchronization signal transferred from the external system and can generate a data control signal DCS which is to be supplied to the data driver 300 and a gate control signal GCS which is to be supplied to the gate driver 200.

To this end, the controller 400 can include a data aligner which realigns input image data to generate image data Data and supplies the image data Data to the data driver 300, a control signal generator which generates the gate control signal GCS and the data control signal DCS by using the timing synchronization signal, an input unit which receives the timing synchronization signal and the input image data transferred from the external system (e.g., host system) and respectively transfers the timing synchronization signal and the input image data to the control signal generator and the data aligner, and an output unit which supplies the data driver 300 with the image data Data generated by the data aligner and the data control signal DCS generated by the control signal generator and supplies the gate driver 200 with the gate control signal GCS generated by the control signal generator.

The external system can perform a function of driving the controller 400 and an electronic device. For example, when the electronic device is a TV, the external system can receive various sound information, video information, and letter information over a communication network and can transfer the received video information to the controller 400. In this situation, the video information can be the input image data.

The power supply 500 can generate various power signals and can supply the generated power signals to the controller 400, the gate driver 200, the data driver 300, and the display panel 10.

Finally, the gate driver 200 can supply gate pulses to the gate lines GL1 to GLg. When the gate pulse generated by the gate driver 200 is supplied to the gate of the switching transistor Tsw1 provided in the pixel P, the switching transistor Tsw1 can be turned on. When the switching transistor Tsw1 is turned on, the data voltage Vdata supplied through the date line DL can be supplied to the pixel P. When a gate-off signal generated by the gate driver 200 is supplied to the switching transistor Tsw1, the switching transistor Tsw1 can be turned off. When the switching transistor Tsw1 is turned off, the data voltage Vdata may not be supplied to the pixel P any longer. A gate signal GS supplied to the gate line GL can include the gate pulse and the gate-off signal.

The gate driver 200 can include a plurality of stages, and the stages can be connected to the gate lines GL1 to GLg.

The stages can be included in the display panel 10, and particularly, can be provided in the display area AA.

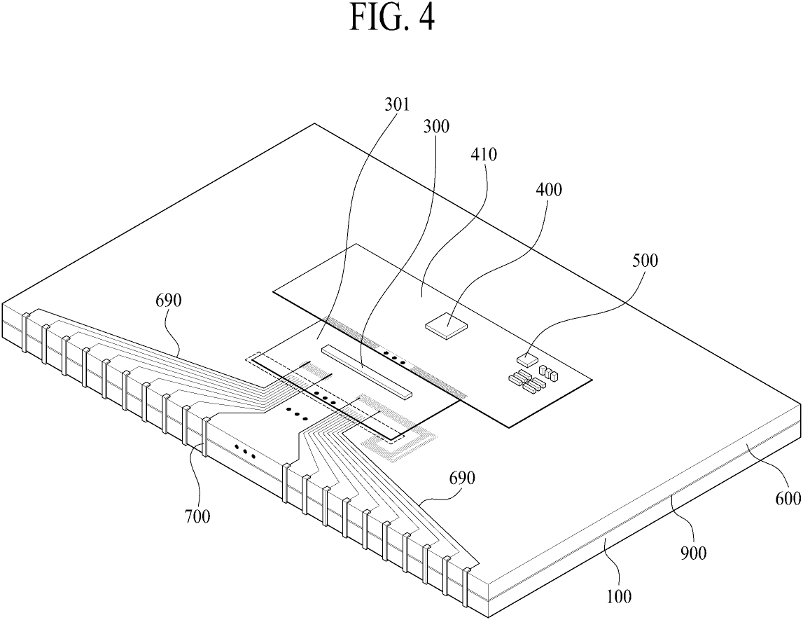

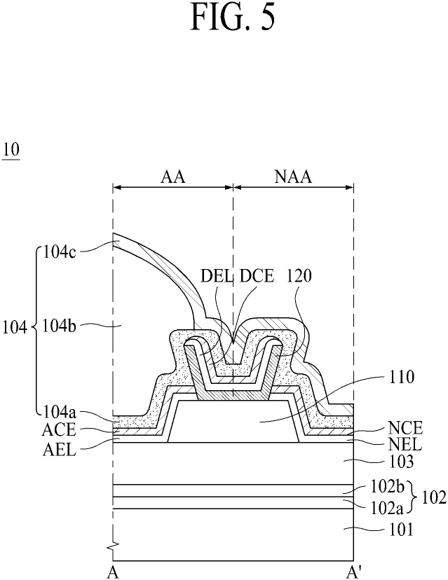

FIG. 3 is a perspective view illustrating a front portion or top view of a light emitting display apparatus according to an embodiment of the present disclosure, and FIG. 4 is a perspective view illustrating a rear portion or back view of the light emitting display apparatus according to an embodiment of the present disclosure.

A display panel 10 applied to the light emitting display apparatus according to an embodiment of the present disclosure can include a first panel 100, which includes pixels P and signal lines 190 arranged in a first direction, and a second panel 600 which is disposed on a rear surface of the first panel 100. The first panel 100 and the second panel 600 can be bonded to each other by an adhesive 900.

First, the signal lines 190 included in the first panel 100 can include data lines DL1 to DLd which transfer data voltages to the pixels P, power lines which transfer driving voltages to the pixels P, gate clock lines which transfer gate clocks to a gate driver 200 provided in a display area AA, and gate power lines which transfer gate driving voltages to the gate driver 200 provided in the display area AA.

First pads connected with the signal lines 190 and routing lines 700 can be provided at a first-side outer portion of the first panel 100. For example, the routing lines 700 can go from the front side of the display panel 10 and wrap around an edge to continue to the rear side of the display panel 10. Here, the first side of the first panel 100 can denote one region of regions configuring a front portion of the first panel 100.

For example, in FIG. 3, the first-side outer portion of the first panel 100 can denote a region where the routing lines 700 are provided. The first pads can be covered by the routing lines 700. In FIG. 3, the first panel 100 where the first pads are at only the first-side outer portion is illustrated as an example of the present disclosure. However, first pads 160 can be further provided in at least one of a second-side outer portion which faces the first-side outer portion with the display area therebetween, a third-side outer portion adjacent to the first-side outer portion, and a fourth-side outer portion which faces the third-side outer portion with the display area therebetween, in addition to the first-side outer portion. Hereinafter, for convenience of description, as illustrated in FIGS. 3 and 4, the display panel 10 where the first pads are provided at only the first-side outer portion will be described as an example of the present disclosure.

Second, as illustrated in FIG. 4, second pads connected with the routing lines 700 can be provided at a first-side outer portion of the second panel 600. The second pads can be covered by the routing lines 700.

The routing lines 700 can be provided on a first lateral surface of the first panel 100 and a first lateral surface of the second panel 600. That is, first ends of the routing lines can be connected with the first pads included in the first panel 100, and the other ends of the routing lines can be connected with the second pads included in the second panel 600.

Link lines 690 connected with the routing lines 700 and second pads, as illustrated in FIG. 4, can be included in the second panel 600. The link lines 690 can be connected with at least one driver. Some of the link lines 690 can be connected with a data driver 300 mounted on a first printed circuit board (PCB) 301, some of the link lines 690 can be connected with a controller 400 mounted on a second PCB 410, and some of the link lines 690 can be connected with a power supply 500 mounted on the second PCB 410.

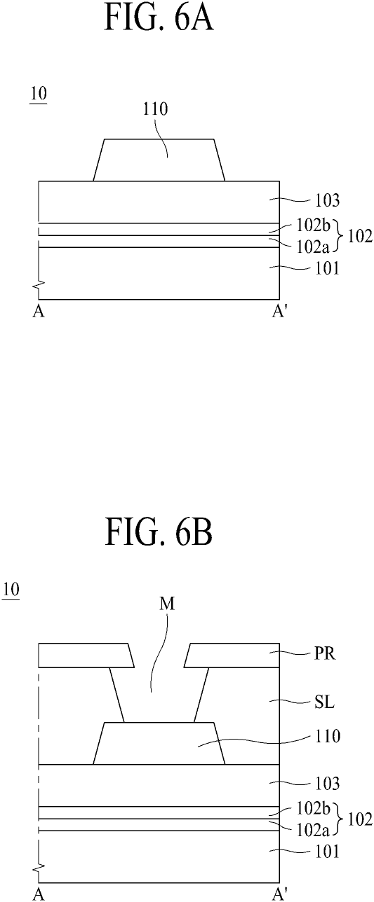

FIG. 5 is an example diagram illustrating a cross-sectional surface taken along line A-A′ illustrated in FIG. 1 and FIG. 3.

As described above, the light emitting display apparatus according to an embodiment of the present disclosure can include the display panel 10, the gate driver 200, the data driver 300, the controller 400, and the power supply 500.

In this situation, as illustrated in FIG. 1, the display panel 10 can be configured as one panel, but as illustrated in FIGS. 3 and 4, the display panel 10 can include the first panel 100 and the second panel 600.

The gate driver 200 can be directly provided in a non-display area, or as illustrated in FIG. 1, the gate driver 200 can be manufactured as a separate element and can be provided in the non-display area. Also, as described above with reference to FIGS. 3 and 4, the gate driver 200 can be provided in a display area AA of the first panel 100 among the first panel 100 and the second panel 600 connected by the routing line 700.

In a situation where a multi-screen display apparatus (or a multi-vision) is manufacturing by connecting light emitting display apparatuses with one another, a width of a non-display area should be minimized for increasing the immersion of a user (e.g., to avoid an appearance of noticeable grid lines between display panels). Accordingly, as illustrated in FIGS. 3 and 4, the present disclosure can be applied to a light emitting display apparatus where a gate driver is provided in the display area AA and thus a non-display area NAA is minimized. However, in a light emitting display apparatus where a gate driver is provided in the non-display area NAA, a width of the non-display area may be needed to be minimized for increasing the immersion of a user. Accordingly, as illustrated in FIG. 1, the present disclosure can also be applied to a light emitting display apparatus where the gate driver is provided in the non-display area NAA.

Therefore, a cross-sectional surface illustrated in FIG. 5 can be a cross-sectional surface taken along line A-A′ in the display panel 10 illustrated in FIG. 1, or can be a cross-sectional surface taken along line A-A′ in the first panel 100 of the display panel 10 illustrated in FIG. 3.

Hereinafter, for convenience of description, the light emitting display apparatus illustrated in FIG. 1 will be described as an example of the present disclosure. Therefore, a description of the display panel 10 described below can be applied to the first panel 100.

The display panel 10, as illustrated in FIG. 5, can include a substrate 101, a circuit layer 102, a planarization layer 103, a dam 110, a division portion 120, a display area emission layer AEL, a display area cathode ACE, a non-display area emission layer NEL, a non-display area cathode NCE, a division portion emission layer DEL, a division portion cathode DCE, and an encapsulation layer 104. Furthermore, the display panel 10 can include an anode which configures a light emitting device ED along with the display area emission layer AEL and the display area cathode ACE.

First, the substrate 101 can be a glass substrate, a flexible substrate or can be a film which includes various kinds of synthetic resins such as polyimide.

The substrate 101 can be divided into a display area AA which displays an image and a non-display area NAA which surrounds the display area AA.

The circuit layer 102 can be provided on the substrate 101.

Transistors and a capacitor configuring a pixel driving circuit PDC can be provided in the circuit layer 102. To this end, the circuit layer 102 can include at least two insulation layers 102a and 102b and metals provided between the at least two insulation layers. A driving transistor Tdr provided in the circuit layer 102 can be connected with the anode configuring the light emitting device ED.

The planarization layer 103 can be provided on the circuit layer 102.

The planarization layer 103 can perform a function of planarizing an upper surface of the circuit layer 102.

The dam 110 can be provided on the planarization layer 103 and can be provided at a boundary between the display area AA and the non-display area NAA. The dam 110 can be providing as a single structure or be provided as a plurality of dams close together. Also, according to an embodiment, the dam 110 can extend around the display area AA in a closed loop shape.

As described above, in the following description, the display area AA and the non-display area NAA can be divided by using the dam as a boundary. That is, a region surrounded by the dam 110 can be the display area AA, and a region outside the dam 110 can be the non-display area NAA.

The dam 110 can be provided in at least one of four outer portions of the display panel 10 illustrated in FIG. 1. In the following description, a light emitting display apparatus where the dam 110 is provided at all of four outer portions will be described as an example of the present disclosure.

The light emitting device ED can be provided on the planarization layer 103 in the display area AA surrounded by the dam 110.

The light emitting device ED can include an anode, an emission layer, and a cathode.

The anode can be provided on the planarization layer 103 and can be provided for each pixel. That is, anodes can be provided on the planarization layer 103.

The anodes can be exposed through opening portions provided in the bank. That is, the bank can cover an upper end of the planarization layer 103 and can cover ends of the anodes.

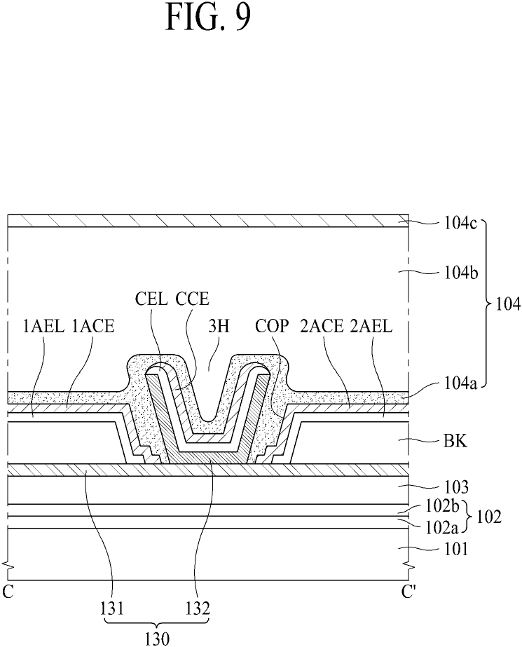

The emission layer can be provided on a whole surface of the display area AA. Therefore, the emission layer can cover upper ends of the anodes exposed through the opening portions provided in the bank Bk and can cover the bank BK (e.g., see FIG. 9).

In the following description, an emission layer provided in the display area AA can be referred to as a display area emission layer AEL, an emission layer provided in the non-display area NAA can be referred to as a non-display area emission layer NEL, and an emission layer provided in the division portion 120 can be referred to as a division portion emission layer DEL. However, a generic name for the display area emission layer AEL, the non-display area emission layer NEL, and the division portion emission layer DEL can be an emission layer.

The display area emission layer AEL can be provided in the display area AA surrounded by the dam 110. The display area emission layer AEL can be provided in all of the display area AA.

The non-display area emission layer NEL can be provided in the non-display area NAA outside the dam 110. The non-display area emission layer NEL can be formed of the same material as a material of the display area emission layer AEL by using the same process.

The division portion emission layer DEL can be provided on an upper surface of the division portion 120. The division portion emission layer DEL can be separated from the display area emission layer AEL and the non-display area emission layer NEL. The display area emission layer AEL and the non-display area emission layer NEL can be separated from each other with the division portion emission layer DEL therebetween. For example, the division portion 120 can effectively cut the emission layer and divide the emission layer into the display area emission layer AEL and the non-display area emission layer NEL, which are separated from each other. The division portion 120 can have a gutter type of shape or a trough type of shape. A cross section of the division portion 120 can take a form of a trapezoid with the upper side being open or missing, or including an opening.

The division portion emission layer DEL can be formed of the same material as a material of the display area emission layer AEL by using the same process (e.g., laid down as a common layer across the panel and be cut by the division portion 120).

That is, the display area emission layer AEL, the non-display area emission layer NEL, and the division portion emission layer DEL can be formed through one process and can be divided based on formed positions thereof.

The cathode can be provided on a whole surface of the display area AA. Accordingly, the cathode can cover the display area emission layer AEL. Similarly, the cathode can be laid down as a common layer across the panel and be cut or divided by the division portion 120, according to an embodiment.

In the following description, a cathode provided in the display area AA can be referred to as a display area cathode ACE, a cathode provided in the non-display area NAA can be referred to as a non-display area cathode NCE, and a cathode provided in the division portion 120 can be referred to as a division portion cathode DCE. However, a generic name for the display area cathode ACE, the non-display area cathode NCE, and the division portion cathode DCE can be a cathode.

That is, the display area cathode ACE can be provided on the display area emission layer AEL, the non-display area cathode NCE can be provided on the non-display area emission layer NEL, and the division portion cathode DCE can be provided on the division portion emission layer DEL. In this situation, the division portion cathode DCE can be separated from the display area cathode ACE and the non-display area cathode NCE (e.g., the division portion cathode DCE can be contained inside a trough part of the division portion 120 or a concave portion of the division portion 120).

The display area cathode ACE and the non-display area cathode NCE can be separated from each other with the division portion cathode DCE therebetween.

The display area cathode ACE, the non-display area cathode NCE, and the division portion cathode DCE can be formed of the same material by using the same process.

That is, the display area cathode ACE, the non-display area cathode NCE, and the division portion cathode DCE can be formed through one process and can be divided based on formed positions thereof (e.g., the division portion 120 can cut or divide the portions of the cathode from each other).

The division portion 120 can be provided on the dam 110 and along the dam 110. For example, the division portion 120 can be formed in a closed loop shape surrounding the display area AA.

A cross-sectional surface of the division portion 120, as illustrated in FIG. 5, can have a shape where a center portion is concave, like a V-shape, a U-shape. Also, the division portion 120 can have a cross-sectional surface having a Y-shape or a multi-ribbed or multi-walled shape, such a W-shape.

That is, a first groove having a concave shape can be provided in an upper surface of the division portion 120, and the first groove can be continuously provided along the dam 110. According to another embodiment, an upper surface of the division portion 120 can have a multi-groove shape in which the grooves extend parallel to each other around the display area AA.

The division portion emission layer DEL and the division portion cathode DCE can be provided in the first groove having a concave shape (for example, the upper surface of the division portion 120).

In this situation, the division portion emission layer DEL can be separated from the display area emission layer and the non-display area emission layer NEL by the division portion 120, and the division portion cathode DCE can be separated from the display area cathode ACE by the division portion 120. For example, the division portion 120 can effectively cut or divide an emission layer into different parts that are separated from each other.

Finally, the encapsulation layer 104 can be provided in the display area AA and the non-display area NAA and can cover the display area cathode ACE, the non-display area cathode NCE, and the division portion cathode DCE.

The encapsulation layer 104 can be formed of at least one layer (e.g., three or more layers).

For example, as illustrated in FIG. 5, the encapsulation layer 104 can include three layers. That is, the encapsulation layer 104 can include a first passivation layer 104a, a second passivation layer 104b, and a third passivation layer 104c.

The first passivation layer 104a can cover the cathode and can perform a function of protecting the cathode. That is, the first passivation layer 104a can cover all of the display area cathode ACE, the non-display area cathode NCE, and the division portion cathode DCE.

Particularly, the first passivation layer 104a can be provided continuously up to the non-display area NAA via the dam 110 and the division portion 120 from the display area AA.

The first passivation layer 104a can include an inorganic material.

The second passivation layer 104b can perform a function of protecting light emitting devices ED from particles (water or oxygen) penetrating into the display panel 10 from the outside. The second passivation layer 104b can be formed of at least one layer.

A material included in the second passivation layer 104b can be liquid having a high density or a viscous property. A liquid material included in the second passivation layer 104b can be coated on the display area AA, and then, move up to the dam 110 and the division portion 120 and may no longer be transferred to the non-display area NAA by the dam 110 and the division portion 120, where the liquid material can be changed to a solid state over time. For example, according to an embodiment, the first passivation layer 104a and the third passivation layer 104c can extend across the display area AA, over the dam 110 and across the non-display area NAA, while the second passivation layer 104b can be much thicker and can be stopped from entering into the non-display area NAA and can terminate over or before the dam 110.

Therefore, the second passivation layer 104b may not be provided in the non-display area NAA outside the dam 110 and can be contained within the display area AA.

A layer configuring the second passivation layer 104b can include an organic material, or can include an inorganic material. According to an embodiment, the second passivation layer 104b can be thicker than both of the first passivation layer 104a and the third passivation layer 104c.

The third passivation layer 104c can cover the first passivation layer 104a and the second passivation layer 104b provided in the non-display area NAA.

That is, the third passivation layer 104c can be provided continuously up to the non-display area NAA via the dam 110 and the division portion 120 from the display area AA.

The third passivation layer 104c can include an inorganic material.

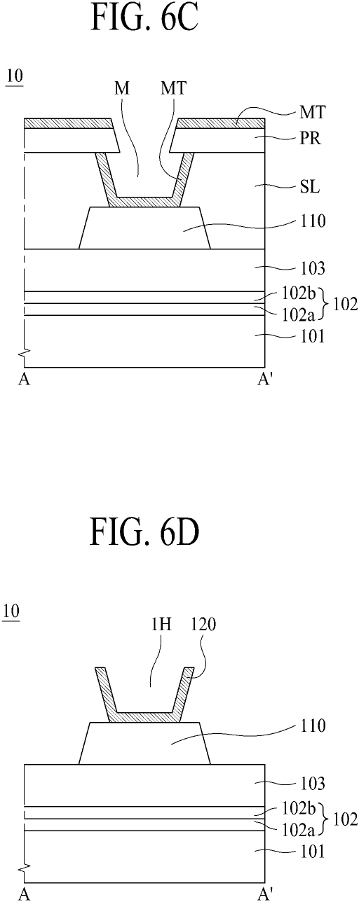

Hereinafter, a method of manufacturing the display panel illustrated in FIG. 5 will be described with reference to FIGS. 5 and 6A to 6F.

FIGS. 6A to 6F are example diagrams illustrating a method of manufacturing a light emitting display apparatus according to an embodiment of the present disclosure. Particularly, FIGS. 6A to 6F are example diagrams illustrating a cross-sectional surface taken along line A-A′ illustrated in FIG. 1 and FIG. 3.

First, as illustrated in FIG. 6A, the circuit layer 102 can be provided on the substrate 101, the circuit layer 102 can be covered by the planarization layer 103, and the dam 110 can be provided on the planarization layer 103.

Subsequently, in order to cover the dam 110 and the planarization layer 103, a shielding layer SL can be deposited on the display area AA and the non-display area NAA, and a photoresist PR can be deposited on the shielding layer SL.

Subsequently, as illustrated in FIG. 6B, the photoresist PR and the shielding layer SL can be etched to expose an upper surface of the dam 110. Therefore, an open region M, corresponding to the dam 110, of the photoresist PR and the shielding layer SL can be formed.

Particularly, an undercut can be formed in the open region M. For example, the shielding layer SL can be etched more than the photoresist PR, and thus, an undercut can be formed between a lower end or underside of the photoresist PR and a lateral surface of the shielding layer SL.

Subsequently, as illustrated in FIG. 6C, a metal material MT can be deposited on the display area AA and the non-display area NAA.

In this situation, a metal material MT provided on an upper surface of the photoresist PR and a metal material MT provided in the open region M can be separated from each other by the undercut formed in the open region M.

Subsequently, as illustrated in FIG. 6D, the photoresist PR and the shielding layer SL can be removed. For example, in this way, a gutter type of structure can be formed on the dam 110, which can have a closed loop shape surrounding all of the display area AA.

In this situation, the metal material MT provided on the upper surface of the photoresist PR can be removed also (e.g., via polishing or etching, etc.). However, the metal material MT provided in the open region M may not be removed and can be left behind to form the division portion 120. The metal material MT provided in the open region M can be the division portion 120.

The division portion 120 can include an inorganic material or an organic material.

For example, the division portion 120 can include an inorganic insulating material such as silicone dioxide (SiO₂) and silicone nitrate (SiNx), or can include a material which functions as a water attractant or a desiccant, such as calcium (Ca) and calcium oxide (CaO).

A cross-sectional surface of the division portion 120, as illustrated in FIG. 6D, can have a shape where a center portion is concave, like a V-shape or a U-shape. According to another embodiment, a cross-sectional surface of the division portion 120 can have a Y-shape or a W-shape. As illustrated in FIG. 6D, a first groove 1H having a concave shape can be provided in the upper surface of the division portion 120. According to another embodiment, the division portion 120 can include multiple parallel grooves.

Subsequently, an emission material and a cathode material can be sequentially deposited on the display area AA and the non-display area NAA.

Subsequently, as illustrated in FIG. 6E, the display area emission layer AEL, the non-display area emission layer NEL, the division portion emission layer DEL, the display area cathode ACE, the non-display area cathode NCE, and the division portion cathode DCE can be formed by using the division portion 120 as a boundary. For example, the division portion 120 can effectively cut and divide a common emission layer and a common cathode layer into different portions.

In this situation, the display area emission layer AEL, the non-display area emission layer NEL, and the division portion emission layer DEL can be separated from one another. Accordingly, the display area emission layer AEL provided in the display area AA can be separated from the non-display area emission layer NEL provided in the non-display area NAA.

Therefore, water penetrating through the non-display area emission layer NEL from the outside of the display panel 10 may not flow into the display area emission layer AEL and can be blocked by the division portion 120. Accordingly, the reliability of light emitting devices ED provided in the display area AA can be enhanced and a bezel area can be further reduced.

Also, the display area cathode ACE, the non-display area cathode NCE, and the division portion cathode DCE can be separated from one another.

Finally, as illustrated in FIG. 6F, the cathode can be covered by the encapsulation layer 104, and thus, the display panel 10 can be manufactured.

The encapsulation layer 104 can include the first passivation layer 104a which covers all of the display area cathode ACE, the non-display area cathode NCE, and the division portion cathode DCE, the second passivation layer 104b which is provided in the display area AA by using the dam 110 as a boundary, and the third passivation layer 104c which covers the second passivation layer 104b provided in the display area AA and the first passivation layer 104a provided in the non-display area NAA.

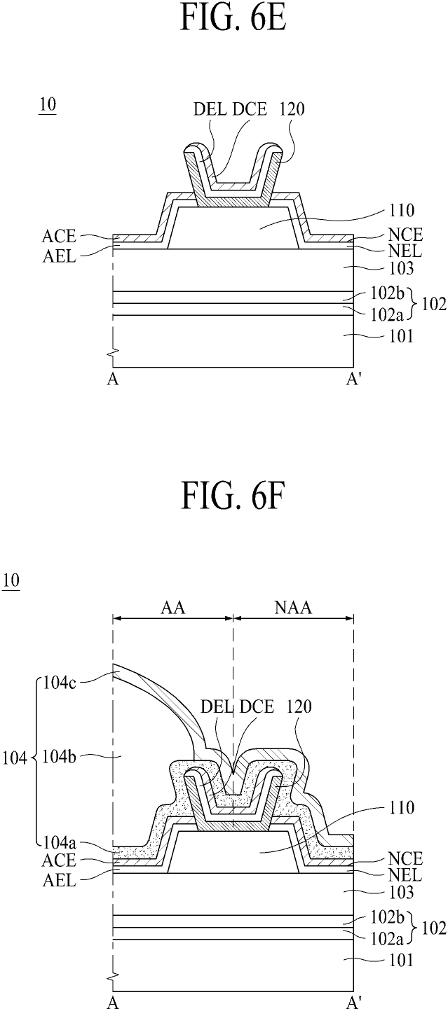

FIG. 7 is another example diagram of a display panel 10 configuring a light emitting display apparatus according to an embodiment of the present disclosure, and particularly, is an example diagram schematically illustrating a one-dimensional configuration of the display panel 10. That is, the display panel 10 including 18 pixels P is illustrated in FIG. 7, but more pixels P can be provided in the display panel 10.

In the display panel described above with reference to FIGS. 1 to 6D, the division portion 120 can be provided in the dam 110 surrounding the display area AA, and the display area emission layer AEL can be separated from the non-display area emission layer NEL by the division portion 120.

The display panel 10 illustrated in FIG. 7, a division portion 120 can also be provided in a dam 110 surrounding a display area AA. In this situation, a display area division portion 121 which performs a function similar to that of the division portion 120 can be provided in a bank BK provided in the display area AA.

That is, a bank BK where an opening portion exposing anodes AE is formed can be provided on a planarization layer 103 in the display area AA, and a display area division portion 121 can be provided in a first direction in an upper surface of the bank BK. Here, as illustrated in FIG. 7, the first direction can be a lengthwise direction of the display panel 10, and particularly, can be a direction vertical to a gate line.

In the following description, the display area division portion 121 can be described as a first display area division portion 121a or a second display area division portion 121b.

That is, the display area division portion 121 can be described as the first display area division portion 121a or the second display area division portion 121b, based on a position thereof.

For example, the first display area division portion 121a can be provided between a first pixel P1 and a second pixel P2 which are adjacent to each other in a second direction vertical to the first direction. Also, the second display area division portion 121b can be provided between a third pixel P3 and a fourth pixel P4 which are adjacent to the first pixel P1 and the second pixel P2 in the first direction. That is, a display area division portion 121 provided between the first pixel P1 and the second pixel P2 can be referred to as a first display area division portion 121a, and a display area division portion 121 provided between the third pixel P3 and the fourth pixel P4 can be referred to as a second display area division portion 121b. For example, a plurality of division portions 121 can be provided between columns of pixels. According to another embodiment, a plurality of division portions 121 can be provided between rows of pixels, or division portions 121 can be provided between columns and rows of pixels in a grid arrangement.

The first display area division portion 121a and the second display area division portion 121b can perform a function of dividing a display area emission layer AEL between two adjacent pixels. Hereinafter, a display area emission layer AEL provided in a first pixel can be referred to as a first display area emission layer, and a display area emission layer AEL provided in a second pixel can be referred to as a second display area emission layer.

Because the display area emission layer AEL are divided between two adjacent pixels, a leakage current does not occur between two adjacent pixels. Accordingly, light can be prevented from being abnormally emitted by a leakage current.

The display area emission layer AEL can be divided by the first display area division portion 121a and the second display area division portion 121b also. Hereinafter, a display area cathode ACE provided on the first display area emission layer can be referred to as a first display area cathode, and a display area cathode ACE provided on the second display area emission layer can be referred to as a second display area cathode.

When the display area cathode ACE is divided between two adjacent pixels, a cathode voltage may not be simultaneously supplied to two pixels.

To prevent such a problem, a cathode connection portion 130 connecting a first display area cathode with a second display area cathode can be provided between the first display area division portion 121a and the second display area division portion 121b.

Because the first display area cathode provided in the first pixel P1 and the second display area cathode provided in the second pixel P2 are connected with each other by the cathode connection portion 130, the cathode voltage may not be simultaneously supplied to the first pixel P1 and the second pixel P2 adjacent to each other.

Moreover, because the third display area cathode provided in the third pixel P3 and the fourth display area cathode provided in the fourth pixel P4 are connected with each other by the cathode connection portion 130, the cathode voltage may not be simultaneously supplied to the third pixel P3 and the fourth pixel P4 adjacent to each other also.

In this situation, a structure material which separates the display area emission layer AEL from the display area cathode ACE may not be provided between the first pixel P1 and the third pixel P3 adjacent to each other in the first direction. Therefore, the first display area emission layer and the third display area emission layer may be continuously formed, and the first display area cathode and the third display area cathode may be continuously formed.

Moreover, a structure material which separates the display area emission layer AEL from the display area cathode ACE may not be provided between the second pixel P2 and the fourth pixel P4 adjacent to each other in the first direction. Therefore, the second display area emission layer and the fourth display area emission layer may be continuously formed, and the second display area cathode and the fourth display area cathode can be continuously formed.

On the other hand, depending on the situation, a structure material which separates a display area emission layer from a display area cathode can be provided between the first pixel P1 and the third pixel P3, and in this situation, a structure material for connecting divided display area cathodes with each other can be provided.

Moreover, as illustrated in FIG. 7, the first display area division portion 121a and the second display area division portion 121b may not only be provided between the first pixel P1 and the second pixel P2 and between the third pixel P3 and the fourth pixel P4, and moreover, can be provided between all pixels adjacent to one another in the second direction.

In this situation, as illustrated in FIG. 7, the cathode connection portion 130 can be provided between all first display area division portions 121a and all second display area division portions 121b adjacent to one another in the first direction. On the other hand, the cathode connection portion 130 can be provided between some first display area division portions 121a and some second display area division portions 121b adjacent to one another in the first direction.

Hereinafter, a structure of the display panel illustrated in FIG. 7 will be described in detail with reference to FIGS. 7 to 9. In the following description, descriptions which are the same as or similar to the descriptions of FIGS. 1 to 7 are omitted or will be briefly given.

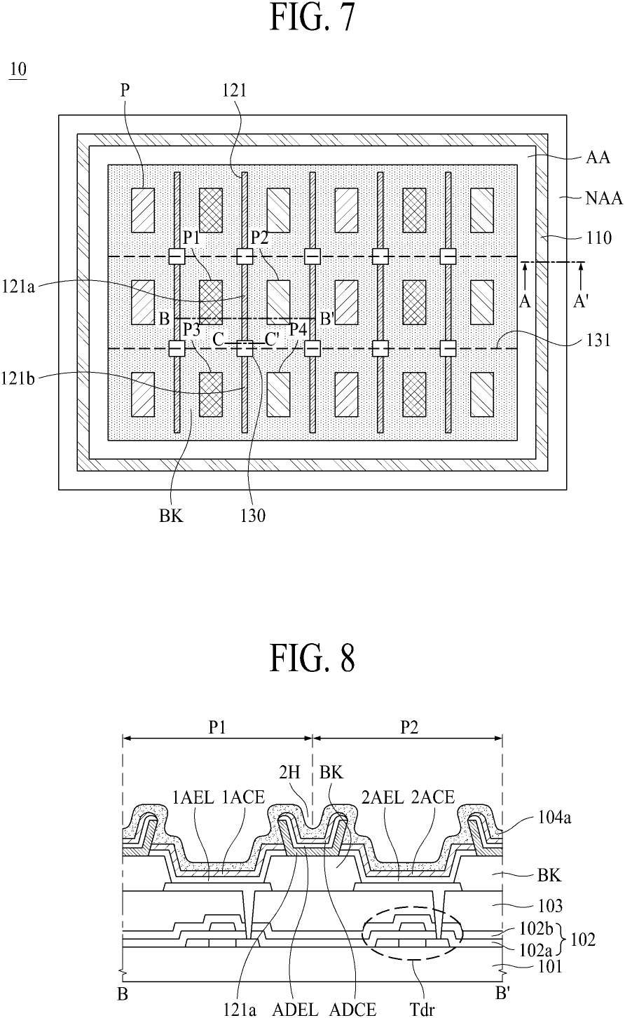

FIG. 8 is an example diagram illustrating a cross-sectional surface taken along line B-B′ illustrated in FIG. 7.

As described above, the first display area division portion 121a and the second display area division portion 121b can be provided in the first direction in the upper surface of the bank BK.

For example, as illustrated in FIGS. 7 and 8, the first display area division portion 121a can be provided between the first pixel P1 and the second pixel P2 adjacent to each other in the second direction vertical to the first direction.

Moreover, as illustrated in FIG. 7, the second display area division portion 121b can be provided between the third pixel P3 and the fourth pixel P4 adjacent to each other in the second direction. In this situation, a structure of the second display area division portion 121b can be the same as that of the first display area division portion 121a illustrated in FIG. 7. Accordingly, a detailed description of the second display area division portion 121b is omitted.

When the first direction is a lengthwise direction of the display panel 10 illustrated in FIG. 7, the second direction can be a widthwise direction of the display panel 10 illustrated in FIG. 7. The first direction can be a direction parallel to a data line DL, and the second direction can be a direction parallel to a gate line GL.

In this situation, the third pixel P3 can be adjacent to the first pixel P1 in the first direction, and the fourth pixel P4 can be adjacent to the second pixel P2 in the first direction.

A display area division portion emission layer ADEL can be provided on the first display area division portion 121a. A first display area emission layer 1AEL included in the first pixel P1, a second display area emission layer 2AEL included in the second pixel P2, and the display area division portion emission layer ADEL can be separated from one another.

That is, a second groove 2H having a concave shape can be provided in an upper surface of the first display area division portion 121a, and the second groove 2H can be provided in the first direction.

A cross-sectional surface of the first display area division portion 121a, as illustrated in FIG. 8, can have a shape where a center portion is concave, like a V-shape or a U-shape. That is, the first display area division portion 121a can have a shape which is similar to that of the division portion 120. According to another embodiment, a cross-sectional surface of the first display area division portion 121a can have a Y-shape or a W-shape.

Therefore, the first display area emission layer 1AEL, the second display area emission layer 2AEL, and the display area division portion emission layer ADEL can be separated from one another.

Accordingly, a leakage current may not occur between the first pixel P1 and the second pixel P2.

A first display area cathode 1ACE can be provided on the first display area emission layer 1AEL, a second display area cathode 2ACE can be provided on the second display area emission layer 2AEL, and a display area division portion cathode ADCE can be provided on the display area division portion emission layer ADEL. In this situation, the first display area cathode 1ACE, the second display area cathode 2ACE, and the display area division portion cathode ADCE can also be separated from one another.

The first display area cathode 1ACE, the second display area cathode 2ACE, and the display area division portion cathode ADCE can be covered by the encapsulation layer 104, and particularly, as illustrated in FIG. 8, can be covered by the first passivation layer 104a.

A cross-sectional surface of the second display area division portion 121b can have a shape where a center portion is concave, like a V-shape or a U-shape. That is, the second display area division portion 121b can have a shape which is similar to that of each of the division portion 120 and the first display area division portion 121a. According to another embodiment, a cross-sectional surface of the first display area division portion 121b can have a Y-shape or a W-shape.

Therefore, a third display area emission layer, a fourth display area emission layer, and a display area division portion emission layer can be separated from one another.

Accordingly, a leakage current may not occur between the third pixel P3 and the fourth pixel P4.

A third display area cathode can be provided on the third display area emission layer, a fourth display area cathode can be provided on the fourth display area emission layer, and a display area division portion cathode can be provided on the display area division portion emission layer. In this situation, the third display area cathode, the fourth display area cathode, and the display area division portion cathode can also be separated from one another.

The third display area cathode, the fourth display area cathode, and the display area division portion cathode can be covered by the encapsulation layer 104, and particularly, can be covered by the first passivation layer 104a.

That is, a structure of the second display area division portion 121b can be formed to be equal to that of the first display area division portion 121a.

The display area division portion 121 can include an inorganic insulating material such as silicone dioxide (SiO₂) and silicone nitrate (SiNx), or can include a material which functions as a water attractant or desiccant such as calcium (Ca) and calcium oxide (CaO), or can include metal.

That is, the first display area division portion 121a and the second display area division portion 121b can be formed of the same material as that of the division portion 120 by using the same process. On the other hand, the first display area division portion 121a and the second display area division portion 121b can be formed of a material which differs from that of the division portion 120, through different processes.

FIG. 9 is an example diagram illustrating a cross-sectional surface taken along line C-C′ illustrated in FIG. 7.

A cathode connection portion 130, where the first display area cathode 1ACE included in the first pixel P1 is connected with the second display area cathode 2ACE included in the second pixel P2, can be provided between the first display area division portion 121a and the second display area division portion 121b.

The cathode connection portion 130, as illustrated in FIGS. 7 and 9, can include a connection line 131 which is provided on the planarization layer 103 and includes metal and a boundary portion 132 which is provided on the connection line 131 exposed through a connection opening portion COP provided in the bank BK.

The connection line 131 can be connected with a power supply 500 which supplies a cathode voltage, or can be provided at only the cathode connection portion 130, or as illustrated in FIG. 7, can be formed as one line and can be provided at a plurality of cathode connection portions 130. The connection line 131 can include metal which enables a voltage or a current to be supplied through the connection line 131. Also, the connection line 131 can prevent a voltage drop for the cathodes.

In this situation, the first display area cathode 1ACE can be provided on the connection line 131 exposed through the connection opening portion COP, and the second display area cathode 2ACE can be provided on the connection line 131 exposed through the connection opening portion COP.

In the connection opening portion COP, the first display area cathode 1ACE and the second display area cathode 2ACE can be provided with the boundary portion 132 therebetween.

Therefore, the first display area cathode 1ACE and the second display area cathode 2ACE can be physically separated from each other with the boundary portion 132 therebetween. Alternatively, the first display area cathode 1ACE and the second display area cathode 2ACE can be connected with the connection line 131 including metal in common. Accordingly, the first display area cathode 1ACE and the second display area cathode 2ACE can be connected with each other through the connection line 131, and thus, the same cathode voltage can be simultaneously supplied to the first display area cathode 1ACE and the second display area cathode 2ACE.

Like the display area division portion 121 and the division portion 120, the boundary portion 132 can include an inorganic insulating material such as silicone dioxide (SiO₂) and silicone nitrate (SiNx), or can include a material which functions as a water getter such as calcium (Ca) and calcium oxide (CaO), or can include metal.

That is, the boundary portion 132 can be formed of the same material as that of each of the display area division portion 121 and the division portion 120 by using the same process. On the other hand, the boundary portion 132 can be formed of a material which differs from that of each of the display area division portion 121 and the division portion 120, through different processes. Also, the boundary portion 132, the display area division portion 121, and the division portion 120 can be formed of different materials through different processes.

A third groove 3H having a concave shape can be provided in an upper surface of the boundary portion 132, and the third groove 3H can be provided in the first direction. In this situation, a direction of the first groove 1H can be the same as a direction of the second groove 2H.

A cross-sectional surface of the boundary portion 132, as illustrated in FIG. 9, can have a shape where a center portion is concave, like a V-shape or a U-shape. That is, the boundary portion 132 can have a shape which is similar to that of each of the division portion 120 and the display area division portion 121. According to another embodiment, a cross-sectional surface of the boundary portion 132 can have a Y-shape or a W-shape.

Therefore, the first display area emission layer 1AEL and the second display area emission layer 2AEL can be separated from each other by the boundary portion 132, and a boundary portion emission layer CEL provided on the upper surface of the boundary portion 132 can be separated from the first display area emission layer 1AEL and the second display area emission layer 2AEL.

Moreover, a boundary portion cathode CCE provided on the boundary portion emission layer CEL can be separated from the first display area cathode 1ACE and the second display area cathode 2ACE. Accordingly, as described above, the first display area cathode 1ACE and the second display area cathode 2ACE can be physically separated from each other with the boundary portion 312 therebetween.

Alternatively, the first display area cathode 1ACE and the second display area cathode 2ACE can be connected with the connection line 131 including metal in common. Accordingly, the same cathode voltage can be simultaneously supplied to the first display area cathode 1ACE and the second display area cathode 2ACE and uniform brightness can be improved for the display panel.

In this situation, a third display area cathode provided in the third pixel P3 and a fourth display area cathode provided in the fourth pixel P4 can be electrically connected with each other through the connection line 131, in the connection opening portion COP. Accordingly, the same cathode voltage can be simultaneously supplied to the third display area cathode and the fourth display area cathode.

Therefore, the same cathode voltage can be simultaneously supplied to the first to fourth pixels P1 to P4 and uniform brightness can be improved for the display panel and a voltage drop can be prevented, even for a large display panel.

That is, according to an embodiment of the present disclosure, because the display area emission layer AEL and the non-display area emission layer NEL are divided through the division portion 120, water penetrating through the non-display area emission layer NEL may not flow into the display area emission layer AEL provided in the display area AA. Accordingly, the reliability of light emitting devices ED provided in the display area AA can be enhanced.

Moreover, according to an embodiment of the present disclosure, display area emission layers AEL provided in two adjacent pixels can be separated from each other by the display area division portion 121. Accordingly, a leakage current can be prevented from occurring between two adjacent pixels.

In this situation, display area cathodes ACE provided in two adjacent pixels can be separated from each other by the display area division portion 121. On the other hand, the display area cathodes ACE divided by the display area division portion 121 can be electrically connected with each other through the cathode connection portion 130. Accordingly, the same cathode voltage can be simultaneously supplied to all pixels provided in the display area AA.

According to an embodiment of the present disclosure, the division portion is provided at an upper portion of the dam provided outside the display area, and the emission layer provided in the display area and the emission layer provided in the non-display area can be divided through the division portion. Accordingly, moisture penetrating from the outside through the emission layer provided in the non-display area cannot flow into the emission layer provided in the display area. Therefore, the reliability of the light emitting display apparatus can be enhanced. Particularly, according to the present disclosure, the reliability of the emission layer can be secured.

Moreover, according to the present disclosure, a separate structure for separating the emission layer can be omitted in the non-display area outside the dam, and thus, the size of the non-display area can be further reduced.

The above-described feature, structure, and effect of the present disclosure are included in at least one embodiment of the present disclosure, but are not limited to only one embodiment. Furthermore, the feature, structure, and effect described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A light emitting display apparatus comprising:
a substrate including a display area for displaying an image and a non-display area surrounding the display area;
a circuit layer disposed on the substrate;
a planarization layer disposed on the circuit layer;
a dam disposed on the planarization layer and located at a boundary between the display area and the non-display area;
a division portion disposed on the dam, the division portion extending along the dam;
a display area emission layer disposed in the display area;
a non-display area emission layer disposed outside the dam, the dam being located between the display area emission layer and the non-display area emission layer; and
a division portion emission layer disposed on an upper surface of the division portion, the division portion emission layer being separated from the display area emission layer and the non-display area emission layer.

2. The light emitting display apparatus of claim 1, further comprising:
a first groove having a concave shape in the upper surface of the division portion,
wherein the first groove extends continuously along the dam.

3. The light emitting display apparatus of claim 2, wherein a cross section of the division portion has a V-shape, a U-shape or a trapezoid shape with an opening at the upper surface of the division portion.

4. The light emitting display apparatus of claim 1, wherein a lower surface of the division portion emission layer is in direct contact with the upper surface of the division portion.

5. The light emitting display apparatus of claim 1, wherein the dam fully surrounds the display area in a closed loop shape.

6. The light emitting display apparatus of claim 1, wherein the division portion fully surrounds the display area in a closed loop shape.

7. The light emitting display apparatus of claim 1, further comprising:
a display area cathode disposed on the display area emission layer;
a non-display area cathode disposed on the non-display area emission layer; and
a division portion cathode disposed on the division portion emission layer, the division portion cathode being separated from the display area cathode and the non-display area cathode.

8. The light emitting display apparatus of claim 7, further comprising:
an encapsulation layer covering the display area cathode, the non-display area cathode, and the division portion cathode.

9. The light emitting display apparatus of claim 1, further comprising:
a bank disposed on the planarization layer in the display area, the bank including an opening portion exposing at least one anode;
a first display area division portion disposed on an upper surface of the bank, the first display area division portion extending in a first direction and being located between a first pixel and a second pixel adjacent to the first pixel in a second direction different than the first direction;
a display area division portion emission layer disposed on the first display area division portion;
a first display area emission layer in the first pixel; and
a second display area emission layer in the second pixel,
wherein the first display area emission layer, the second display area emission layer, and the display area division portion emission layer are separated from one another.

10. The light emitting display apparatus of claim 9, further comprising:
a second groove having a concave shape is provided in an upper surface of the first display area division portion,
wherein the second groove extends in the first direction.

11. The light emitting display apparatus of claim 2, wherein a cross section of the first display area division portion has a V-shape, a U-shape or a trapezoid shape with an opening at the upper surface of the first display area division portion.

12. The light emitting display apparatus of claim 9, further comprising:
a first display area cathode disposed on the first display area emission layer;
a second display area cathode disposed on the second display area emission layer;
a display area division portion cathode disposed on the display area division portion emission layer,
wherein the first display area cathode, the second display area cathode, and the display area division portion cathode are separated from one another.

13. The light emitting display apparatus of claim 12, further comprising:
an encapsulation layer covering the first display area cathode, the second display area cathode, and the display area division portion cathode.

14. The light emitting display apparatus of claim 12, further comprising:
a second display area division portion disposed on an upper surface of the bank, the second display area division portion extending in the first direction and being located between a third pixel and a fourth pixel adjacent to the first pixel and the second pixel in the first direction; and
a cathode connection portion disposed between the first display area division portion and the second display area division portion, the cathode connection portion being connected to the first display area cathode and the second display area cathode.

15. The light emitting display apparatus of claim 14, wherein the cathode connection portion comprises:
a connection line disposed on the planarization layer, the connection line including a metal; and
a boundary portion disposed on the connection line exposed through a connection opening portion in the bank,
wherein the first display area cathode is disposed on a first portion of the connection line exposed through the connection opening portion,
wherein the second display area cathode is disposed on a second portion of the connection line exposed through the connection opening portion, and
wherein the boundary portion is disposed in the connection opening portion and located between the first display area cathode and the second display area cathode.

16. The light emitting display apparatus of claim 15, further comprising:
a third groove having a concave shape in an upper surface of the boundary portion,
wherein the third groove extends in the first direction.

17. The light emitting display apparatus of claim 2, wherein a cross section of the boundary portion has a V-shape, a U-shape or a trapezoid shape with an opening at the upper surface of the boundary portion.

18. A light emitting display apparatus comprising:
a dam disposed on a substrate and located at a boundary between a display area and a non-display area;
a division portion disposed on the dam;
a display area emission layer disposed on a first side of the dam and in the display area;
a non-display area emission layer disposed on a second side of the dam and in the non-display area; and
a division portion emission layer disposed on the division portion,
wherein the division portion emission layer, the display area emission layer and the non-display area emission layer are separated from each other.

19. The light emitting display apparatus of claim 18, wherein a cross section of the division portion has a V-shape, a U-shape or a trapezoid shape with an opening at an upper surface of the division portion.

20. The light emitting display apparatus of claim 18, further comprising:
an encapsulation layer including a first passivation layer, a second passivation layer, and a third passivation layer,
wherein the passivation layer is disposed across the display area and terminates before the non-display area, and
wherein the first passivation layer and the third passivation layer both extend across the display area, over the division portion and into the non-display area.
